(19) United States
(12) Patent Application Publication
(10) Pub. No.: US 2025/0316534 A1
(43) Pub. Date: Oct. 9, 2025

(54) METHOD FOR FORMING SEMICONDUCTOR STRUCTURE WITH METAL PORTIONS MADE OF DIFFERENT MATERIALS

(71) Applicant: TAIWAN SEMICONDUCTOR MANUFACTURING COMPANY, LTD., Hsinchu (TW)

(72) Inventors: Yi-Hsing YU, Hsinchu (TW); Chen-Hao WU, Hsinchu (TW); Chia Jou LIU, Hsinchu (TW); Huang-Lin CHAO, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 18/630,287

(22) Filed: Apr. 9, 2024

(51) Int. Cl. H01L 21/768; C09G 1/02; H01L 21/321; H01L 21/8234; H01L 23/29; H01L 23/31; H01L 23/522; H01L 23/528; H01L 23/532; H01L 29/06; H01L 29/417; H01L 29/423; H01L 29/66; H01L 29/775; H01L 29/786

(52) U.S. Cl. CPC H01L 21/7684; C09G 1/02; H01L 21/3212; H01L 21/76814; H01L 23/291; H01L 23/3171; H01L 23/5226; H01L 23/5283; H01L 23/53242; H01L 23/53266; H01L 23/53295; H10D 30/6219; H10D 30/6729; H10D 84/0149; H10D 84/038; H10D 30/014; H10D 30/024; H10D 30/43; H10D 30/6735; H10D 30/6757; H10D 62/121

(57) ABSTRACT

A method for forming a semiconductor structure includes: performing a chemical mechanical polishing (CMP) process on a base structure including therein a first metal portion and a second metal portion using an acidic polishing slurry, the acidic polishing slurry including an active chemical and an inhibitor which protects the first metal portion from being overpolished, a metal material of the first metal portion being different from a metal material of the second metal portion.

### BACKGROUND

In the fabrication of semiconductor structures, materials and process flows are adjusted so as to meet the requirements of integrated circuits with shrinking size. For instance, many different approaches are developed to obtain interconnects with low contact resistance and high conduction speed, so that the performance of the semiconductor structures can be enhanced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 5 are schematic views illustrating intermediate stages of the method for manufacturing the semiconductor structure in accordance with some embodiments.

FIG. 6 is a diagram illustrating processing windows of different chemical mechanical polishing (CMP) processes for removing ruthenium at different pH and potential.

FIG. 7 is a schematic view illustrating effect of an inhibitor in a polishing slurry in accordance with some embodiments.

FIG. 8 is a flow diagram illustrating another method for manufacturing a semiconductor structure in accordance with some embodiments.

FIGS. 9 to 12 are schematic views illustrating intermediate stages of the another method for manufacturing the semiconductor structure in accordance with some embodiments.

FIGS. 13 to 16 are schematic views illustrating other application of the methods for manufacturing a semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

The present disclosure is directed to a method for manufacturing a semiconductor structure having conducting elements that include different metallic materials. The conducting elements may be located at front-end-of-line (FEOL), such as metal gate, at middle-end-of-line (MEOL), such as contact vias (gate contact (VG), source/drain contact (MD), via on source/drain via contact (VD)), at back-end-of-line (BEOL), or at super power rail (feed through via (FTV) and back side via (VB), each interconnecting an element at the FEOL to an element at a back side of the semiconductor structure). Other suitable conducting elements are within the contemplated scope of the present disclosure. Tungsten (W) and molybdenum (Mo) have bulk conductivities that are higher than a bulk conductivity of ruthenium (Ru), and thus are widely used in manufacturing semiconductor structures. In recent years, ruthenium, in nano-scale or angstrom-scale, may have better conductivity than tungsten and molybdenum. In order to reduce a cell height and enhance performance of a semiconductor device in the semiconductor structure (e.g., increased speed of the semiconductor device and/or reduced contact resistance between elements of the semiconductor structure), and to take into account the current operation parameters for manufacturing the semiconductor structure, different metallic materials, such as ruthenium, tungsten and molybdenum, may be employed in the making of the conducting elements in the semiconductor structure. In order to obtain the conducting elements that are made of different metal materials and that have top surfaces located at substantially the same level in the semiconductor structure, metal portions (respectively formed into the conducting elements) may be subjected to a planarization process, such as a chemical mechanical polishing (CMP) process.

In the present disclosure, a first metal portion including, e.g., tungsten, and a second metal portion including, e.g., ruthenium, are subjected to the CMP process. A top surface of the first metal portion and a top surface of the second metal portion, before performing the CMP process, may be located at different levels. For instance, in some embodiments, the second metal portion may have a part that is blanket deposited over the first metal portion, i.e., the top surface of the first metal portion is located beneath a bottom surface of the blanket deposited part of the second metal portion. In order to efficiently remove the blanket deposited part of the second metal portion, a first CMP process may be first performed to remove the blanket deposited part, while the first metal portion is refrained from being polished. The first CMP process is performed using a first polishing slurry that includes a first active chemical and a first inhibitor. The first active chemical removes the blanket deposited part of the second metal portion, while the first inhibitor protects, if any, part(s) of the first metal portion, which are undesirably or unavoidably exposed, from being overpolished during the first CMP process. After the first CMP process, the second metal portion may have a first polished surface located at a level still higher than a level of the top surface of the first metal portion. The first polished surface of the second metal portion is then subjected to a second CMP process. The second CMP process is performed using a second polishing slurry that is different from the first polishing slurry. The second polishing slurry includes a second active chemical and a second inhibitor. The second inhibitor protects the first metal portion from being overpolished, and may be the same as the first inhibitor in accordance with some embodiments. The second metal portion merely reacts with the second active chemical, and is polished and planarized by mechanical removal. In some embodiments, the first metal portion is also subjected to the second CMP process. The first metal portion is polished and planarized mainly by chemical removal under the effect of the second active chemical and the second inhibitor. As such, each of the first metal portion and the second metal portion are formed into different conductive elements with top surfaces thereof at substantially the same level (e.g., a height difference is less than about 5 nm). In some cases, the first CMP process may be omitted if desired, or when the second metal portion does not have the blanket deposited part.

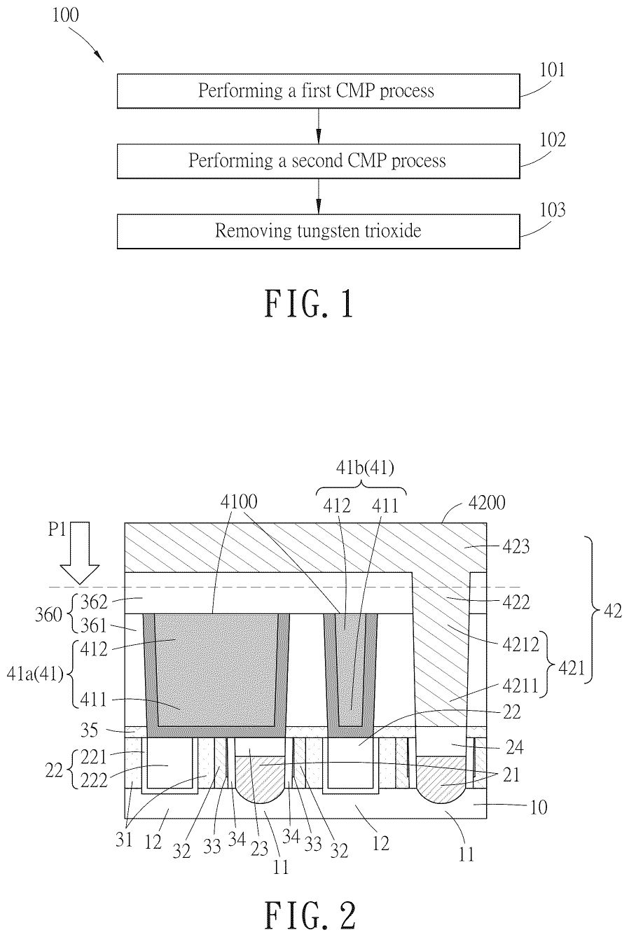

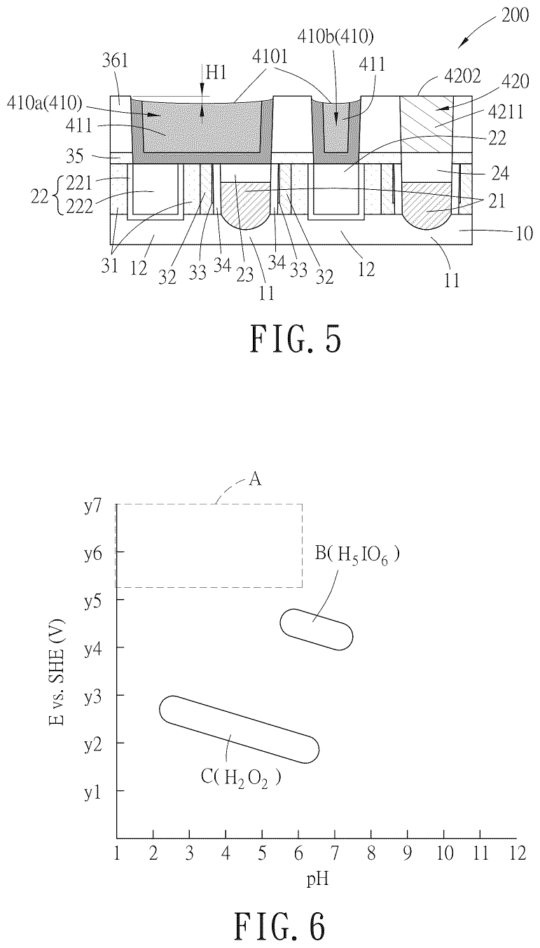

FIG. 1 is a flow diagram illustrating a method 100 for manufacturing the semiconductor structure (for example, the semiconductor structure 200 shown in FIG. 5) in accordance with some embodiments. FIGS. 2 to 5 illustrate schematic views of intermediate stages of the method 100 in accordance with some embodiments. Some repeating structures are omitted in FIGS. 2 to 5 for the sake of brevity. Additional steps can be provided before, after or during the method, and some of the steps described herein may be replaced by other steps or be eliminated.

FIGS. 2 to 5 exemplarily illustrate intermediate stages of forming a first metal portion 41 (see FIG. 2) and a second metal portion 42 respectively into a first conducting element 410 (see FIG. 5) and a second conducting element 420. In this example, both the first conducting element 410 and the second conducting element 420 serve as metal vias in the MEOL, but are not limited thereto. In other cases, the first and second conducting elements 410, 420 may each independently serve as any other suitable interconnect elements, such as gate contact, source/drain contact, other backside contact (e.g., metal lines), etc.

Referring to FIG. 1 and the example illustrated in FIG. 2, the method 100 begins at step 101, where a base structure is subjected to a first chemical mechanical polishing (CMP) process (see the arrow P1).

The base structure shown in FIG. 2 exemplarily includes a fin field-effect-transistor (FinFET) device, but is not limited thereto. The FinFET device is formed on a substrate (not shown) and includes a fin 10, which has source/drain portions 11 that are spaced apart from each other and that are connected by channels 12. The substrate may be made of elemental semiconductor materials, such as silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate may be doped with p-type impurities or n-type impurities, or undoped. In addition, the substrate may be a bulk silicon substrate, a silicon-on-insulator (SOI) substrate, or a germanium-on-insulator (GOI) substrate. The fin 10 may include for example, but not limited to, silicon, silicon germanium, silicon boride, other suitable materials, or combinations thereof. The source/drain portions 11 may include n-type dopants such as phosphorous, arsenic, or antimony, or p-type dopants such as germanium, boron, aluminum, gallium, or indium. The FinFET device further includes gate units 22 that are respectively formed on the channels 12. Each of the gate units 22 includes a gate dielectric 221 and a gate electrode 222. The gate dielectric 221 may include a dielectric material, such as silicon oxide, silicon nitride, silicon oxynitride, hafnium oxide, or the likes, or combinations thereof. The gate electrode 222 may include a conductive material such as a metal, a metal-containing nitride, a metal-containing silicide, a metal-containing carbides, or the likes, or combinations thereof. The gate electrode 222 is spaced apart from a respective one of the channels 12 by the gate dielectric 221. Each of the gate units 22 are sandwiched between a pair of gate spacers 31. The gate spacers 31 may include a dielectric material, such as a silicon carbon-containing dielectric material, a silicon oxide-containing material, silicon nitride, other suitable materials, or combinations thereof. Source/drain contacts 21 are respectively formed in contact with the source/drain portions 11. The source/drain contacts 21 may include aluminum, titanium, tantalum, cobalt, copper, tungsten, ruthenium or the likes, or combinations thereof. In some embodiments, each of the source/drain contacts 21 may be formed with a multi-layered structure so as to include more than one metal layers. The source/drain contacts 21 are spaced apart from the gate units 22 by a contact etch stop layer 32 and are formed in an interlayer dielectric (ILD) 33. Each of the source/drain contacts 21 is sandwiched between a pair of silicon nitride liners 34 located with the ILD 33. The base structure also includes an etch stop layer 35 and a dielectric feature 360 disposed over the FinFET device. The dielectric feature 360 includes a lower dielectric layer 361 and an upper dielectric layer 362 formed over the lower dielectric layer 361. The ILD 33 and the etch stop layer 35 may include a dielectric material such as silicon oxide, silicon nitride, or the likes, or combinations thereof. The dielectric feature 360 may include a silicon oxide-containing material. Other suitable materials and/or configurations for the base structure are within the contemplated scope of the present disclosure.

The base structure further includes the first metal portion 41, which is to be formed into the first conducting element 410 (see FIG. 5) that interconnects the FinFET device with other electronic components in a final product. As exemplarily shown in FIG. 2, there are two (but is not limited thereto) first metal portions respectively denoted as 41a and 41b. Both of the first metal portions 41a, 41b include tungsten. In some embodiments, the first metal portions 41a, 41b each includes a main body (with a lighter shade) that is formed by a chemical vapor deposition (CVD) process, and a liner layer (with a darker shade) that is formed by a physical vapor deposition (PVD) process. Other suitable processes for forming the first metal portions 41a, 41b are within the contemplated scope of the present disclosure. In other embodiments, the first metal portions 41a, 41b may include molybdenum. The first metal portions 41a, 41b are formed in a lower dielectric layer 361 of the dielectric feature 360, and penetrate through the etch stop layer 35 to be in contact with the FinFET device. The first metal portion 41a is in contact with the left gate unit 22 and is connected to the left source/drain contact 21 through a left metal part 23, thereby being connected to the FinFET device. The left metal part 23 may include ruthenium (Ru), tungsten (W) or molybdenum (Mo). The first metal portion 41b is in contact with the right gate unit 22, thereby being connected to the FinFET device. Other suitable configurations for the first metal portions 41a, 41b are within the contemplated scope of the present disclosure. In the following description, the first metal portions 41a, 41b are collectively referred as the first metal portion 41. The first metal portion 41 has a top surface 4100 underneath the upper dielectric layer 362.

The base structure further includes the second metal portion 42, which is to be formed into the second conducting element 420 (see FIG. 5) that interconnects the FinFET device with other electronic components in a final product. The second metal portion 42 is connected to the right source/drain contact 21 through a right metal part 24, thereby being connected to the FinFET device. The right metal part 24 may include ruthenium (Ru), tungsten (W) or molybdenum (Mo). The second metal portion 42 is different from the first metal portion 41 in term of materials thereof, that the second metal portion 42 includes ruthenium. In some embodiments, both the left and right metal parts 23, 24 are made of the same material as the second metal portion 42. In addition, the second metal portion 42 has a top surface 4200 which is located at a level higher than a level of the top surface 4100 of the first metal portion 41. Specifically, the second metal portion 42 has a lower part 421 in the lower dielectric layer 361, a middle part 422 in the upper dielectric layer 362, and an upper part 423 on the upper dielectric layer 362. The lower part 421, the middle part 422 and the upper part 423 are connected to each other, and the second metal portion 42 is configured as a continuous structure. The upper part 423 may be a blanket deposited part over the first metal portion 41. In some embodiments, the second metal portion 42 may be formed by forming an opening (not shown) penetrating through the dielectric feature 360 and the etch stop layer 35, followed by overfilling the opening, and blanket depositing over the upper dielectric layer 362.

The base structure is subjected to the first CMP process that is performed using a first polishing slurry, so as to remove the upper part 423 of the second metal portion 42. The first CMP process may terminate at the upper dielectric layer 362, such that the first metal portion 41 remains intact after the first CMP process. The first polishing slurry may include a first active chemical that readily reacts with and etches the upper part 423 of the second metal portion 42, so as to efficiently remove the upper part 423 at a high removal rate. In some embodiments, the first active chemical is a strong oxidizing agent, such as orthoperiodic acid (H₅IO₆). The first polishing slurry may be neutral, or alkaline, so as to avoid generation of hazardous ruthenium tetroxide (RuO₄). For instance, pH of the first polishing slurry may be controlled to range from about 5.5 to about 7.5. FIG. 6 shows processing windows of different CMP processes for removing ruthenium at different pH and potential. As shown in FIG. 6, Y axis represents potential (E) with respect to standard hydrogen electrode (SHE) in terms of voltage (V), wherein y1, y2, y3, y4, y5, y6 and y7 are all positive values, and y1<y2<y3<y4<y5<y6<y7, whereas X axis represents pH ranging from 1 to 12. It should be noted that ruthenium is present in the form of hazardous ruthenium tetroxide at region A. Region B denotes a process window of reaction between ruthenium and orthoperiodic acid. It is noted that when ruthenium is etched within the pH ranging from about 5.5 to about 7.5 using orthoperiodic acid, hazardous ruthenium tetroxide is not detected.

In addition, in order to further protect the first metal portion 41 from being etched by the first active chemical if part(s) (not shown) of the first metal portion 41 are undesirably or unavoidably exposed in the first CMP process, the first polishing slurry may include a first inhibitor that inhibits the first metal portion 41 from being etched by the first active chemical. The first inhibitor may be a cationic surfactant with strong nitrogen cation(s). In some embodiments, the first inhibitor may include cetyltrimethylammonium bromide (CTAB), or the likes. The first polishing slurry may also include a first abrasive (e.g., abrasive particles), or other suitable components, to facilitate the removal of the upper part 423.

In the first CMP process, in addition to the upper part 423 of the second metal portion 42, an upper region of the upper dielectric layer 362, and an upper region of the middle part 422 of the second metal portion 42 may also be removed. After the first CMP process, the middle part 422 of the second metal portion 42 is exposed.

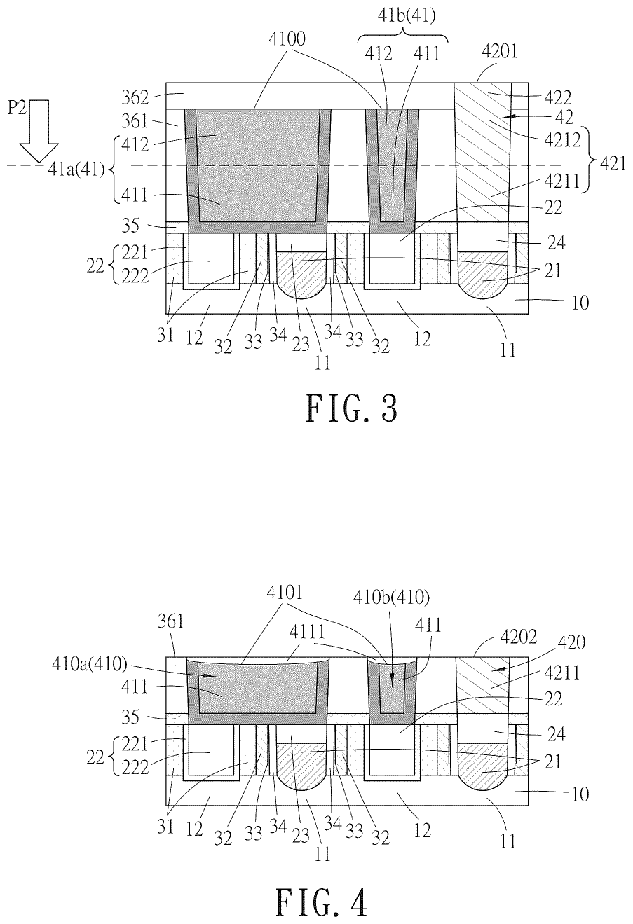

By completing step 101, as shown in FIG. 3, the top surface 4100 of the first metal portion 41 remain intact, and may be covered by a remaining portion of the upper dielectric 362. The second metal portion 42 has a first polished surface 4201, which is located at a level higher than the level of the top surface 4100 of the first metal portion 41.

Referring to FIG. 1 and the example illustrated in FIG. 3, the method 100 proceeds to step 102, where the base structure is subjected to a second chemical mechanical polishing (CMP) process (see the arrow P2). The second metal portion 42 is further polished, such that after the second CMP process, the first and second metal portions 41, 42 are formed to have top surfaces thereof located at substantially the same level.

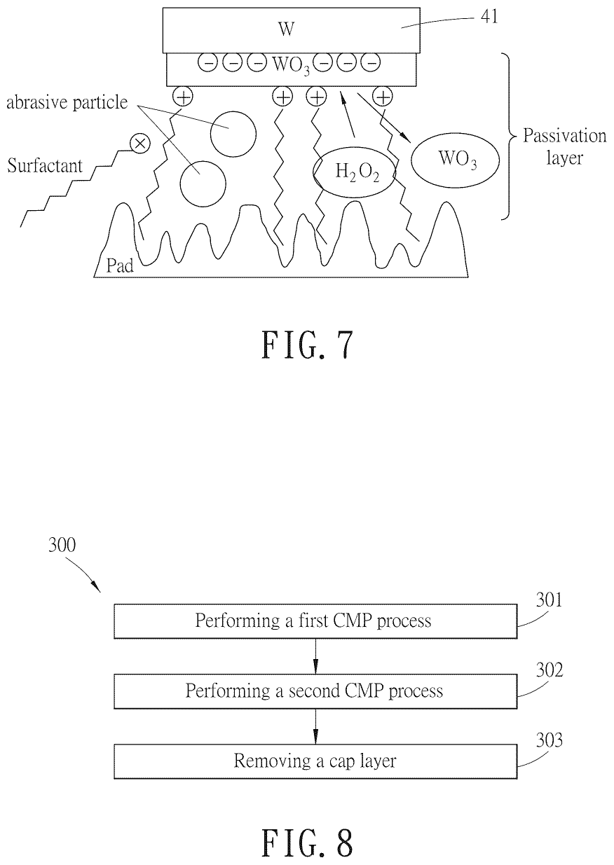

In some embodiments, as shown in FIG. 3, the first metal portion 41 made of tungsten, and the second metal portion 42 made of ruthenium, are co-polished using a second polishing slurry. The second polishing slurry includes a second active chemical, a second inhibitor, and a second abrasive (e.g., abrasive particles shown in FIG. 7). The second polishing slurry is different from the first polishing slurry at least in that the second active chemical is different from the first active chemical. In some embodiments, the second active chemical includes an oxidizing agent that is weaker than the first active chemical, in terms of oxidizing capability, so as to avoid overpolishing of the first metal portion 41. In some embodiments, the second active chemical is hydrogen peroxide (H₂O₂). In some embodiments, in absence of the second inhibitor, the second active chemical has a first etching rate with respect to the first metal portion 41, and a second etching rate with respect to the second metal portion 42, and the first etching rate is greater than the second etching rate. That is, by applying the second active chemical but without the second inhibitor, the first metal portion 41 is etched faster than the second metal portion 42. The second active chemical reacts and etches the first metal portion 41 in a controlled manner so as to avoid overpolishing of the first metal portion 41. In some embodiments, the second polishing slurry is acidic, so that a surface region of tungsten reacts with hydrogen peroxide to form tungsten trioxide. The resultant surface region of tungsten trioxide is a passivating region and is in a solid form to protect tungsten beneath the tungsten trioxide from further oxidation. In some embodiments, the second polishing slurry may be controlled at a pH ranging from about 2.2 to about 6.5. In some embodiments, to ensure formation of tungsten trioxide, pH of the second polishing slurry may be controlled to be not greater than about 5, such as from about 2.2 to about 5, from about 2.2 to about 4, or from about 2.2 to about 3. FIG. 7 is a schematic diagram illustrating effect of an inhibitor on avoiding overpolishing of the first metal portion 41. It is noted that the tungsten trioxide is negatively charged. In order to further protect the first metal portion 41, the second inhibitor may be a cationic surfactant. In some embodiments, the cationic surfactant has strong nitrogen cation(s). In other embodiments, the cationic surfactant may have a long carbon chain (see FIG. 7). In certain embodiments, the cationic surfactant may have a long carbon chain with strong nitrogen cation(s). Examples of the second inhibitor may include cetyltrimethylammonium bromide (CTAB), or the likes, but are not limited thereto. In certain embodiments, the second inhibitor is identical to the first inhibitor of the first polishing slurry. As illustrated in FIG. 7, the positively charged cationic surfactant physically and electrostatically adsorbs on and protects the negatively charged tungsten/tungsten trioxide surface, such that, in step 102, a passivation layer (a tungsten trioxide layer with the cationic surfactant adsorbed thereon) is formed to protect the first metal portion 41. Moreover, a softer polishing pad may be employed to reduce desorption of the cationic surfactant from the tungsten trioxide, and thus further protect the first metal portion 41 from being overpolished. In some embodiments, the polishing pad may have a hardness of not greater than approximately 47 shore D, or not greater than approximately 55 shore A, such as ranging from about 11 shore A to about 55 shore A. In some embodiments, when the hardness of the polishing pad ranges from about 11 shore A to about 21.5 shore A, the first metal portion 41 is less likely to be overpolished.

In the second CMP process, an upper region 412 of the first metal portion 41 is removed together with the middle part 422 and an upper region 4212 of the lower part 421 of the second metal portion 42. It is noted that in the second CMP process, the first metal portion 41 made of tungsten is polished by mainly the chemical etching due to the second active chemical. The second active chemical has merely little, or even no reaction with the second metal portion 42 made of ruthenium. The second metal portion 42 is polished by mainly mechanical polishing. Referring back to FIG. 6, region C shows process window of ruthenium upon reaction with hydrogen peroxide. Despite in acidic condition, ruthenium has a relatively low potential, and thus is exempted from being in the state of hazardous ruthenium tetroxide. In addition, the upper dielectric layer 362 and an upper region of the lower dielectric layer 361 are also removed in the second CMP process.

By completing step 102, for the first metal portion 41, a lower region 411 thereof remains and is exposed from the lower dielectric layer 361; and for the second metal portion 42, a lower region 4211 of the lower part 421 remains and is exposed from the lower dielectric layer 361. FIG. 4 illustrates the intermediate structure after completing step 102, in which the first metal portion 41 (see FIG. 3) is formed into a first conducting element 410 that includes the lower region 411, and the second metal portion 42 is formed into a second conducting element 420 that includes the lower region 4211. The lower region 411 has an upper zone 4111 including mainly tungsten trioxide due to reaction between tungsten (of the first metal portion 41, see FIG. 3) and the second active chemical of the second polishing slurry during the second CMP process.

Referring to FIG. 1 and the example illustrated in FIG. 5, the method 100 proceeds to step 103, where tungsten trioxide present in the upper zone 4111 of the first conducting element 410 (see FIG. 4) is removed, since tungsten trioxide might undesirably affect electrical conductivity of the first conducting element 410.

Tungsten trioxide may be reduced by hydrogen through a chemical reaction, or a plasma sputtering process. In some embodiments, tungsten trioxide may be removed to form a recess with a height H1 ranging from about 2 nm to about 5 nm.

In some embodiments, by completing step 102, an interconnect level including the first and second conducting elements 410, 420 is obtained, and may be directly used for further processing, such as forming a next interconnect level (not shown) thereon. The next interconnect level may include a third conducting element (not shown) that is connected to the first conducting element 410. As such, forming the next interconnect level may include forming another dielectric layer (not shown), patterning the another dielectric layer, removing the upper zone 4111 of the first conducting element 410 shown in FIG. 4, followed by a metal deposition process to form the third conducting element. The removal of the upper zone 4111 may serve as the step 103 of the method 100.

By completing step 103, the semiconductor structure 200 is obtained. The semiconductor structure 200 includes the first and second conducting elements 410, 420, wherein the first conducting element 410 has a top surface 4101, and the second conducting element 420 has a top surface 4202. The two top surfaces 4101, 4202 are substantially at the same level.

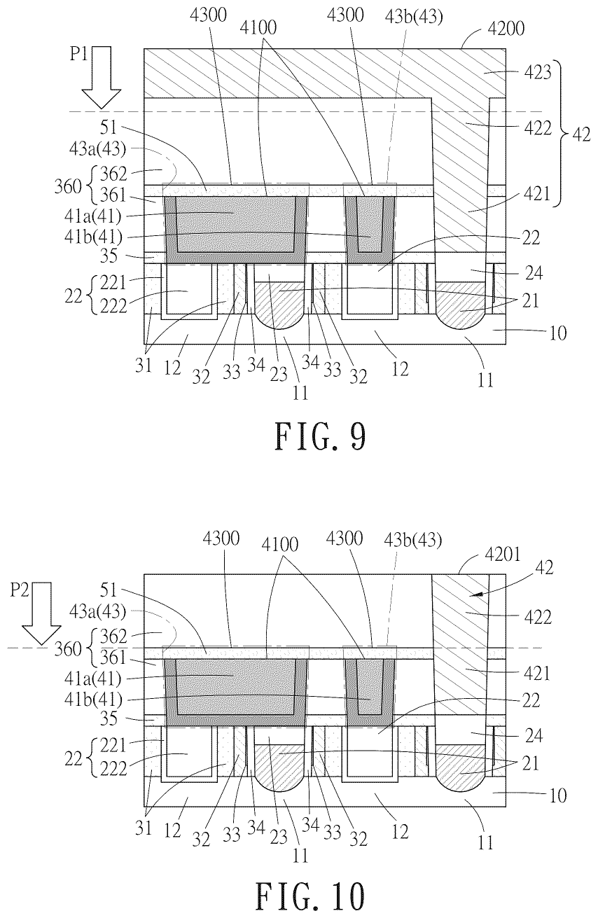

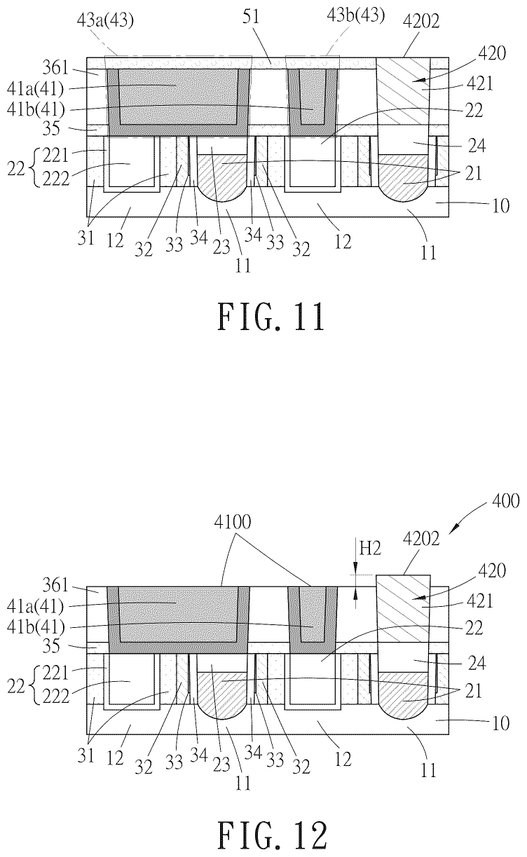

A semiconductor structure 400 shown in FIG. 12 is similar to the semiconductor structure 200 shown in FIG. 5 but is formed by a different method. FIG. 8 is a flow diagram illustrating a method 300 for manufacturing the semiconductor structure (for example, the semiconductor structure 400 shown in FIG. 12) in accordance with some embodiments. FIGS. 9 to 12 illustrate schematic views of intermediate stages of the method 300 in accordance with some embodiments. Some repeating structures are omitted in FIGS. 9 to 12 for the sake of brevity. Additional steps can be provided before, after or during the method, and some of the steps described herein may be replaced by other steps or be eliminated.

Referring to FIG. 8 and the example illustrated in FIG. 9, the method 300 begins at step 301, where a base structure is subjected to a first chemical mechanical polishing (CMP) process (see the arrow P1).

The base structure shown in FIG. 9 is similar to the base structure shown in FIG. 2, except that a silicon nitride cap layer 51 is formed between the lower dielectric layer 361 and the upper dielectric layer 362, and over the first metal portion 41a (on the left) and the first metal portion 41b (on the right). The second metal portion 42 penetrates through the silicon nitride cap layer 51. In some embodiments, the silicon nitride cap layer 51 has a thickness ranging from about 3 nm to about 5 nm.

In some embodiments, the first metal portions 41a, 41b each includes tungsten to serve as a tungsten part. In some embodiments, the silicon nitride cap layer 51 is disposed on and in direct contact with the tungsten parts (i.e., the first metal portions 41a, 41b). The first metal portion 41a, collaborates with a portion of the silicon nitride cap layer 51 located thereon to form a tungsten-containing portion (see the region denoted by the numeral 43a). The first metal portion 41b, collaborates with a portion of the silicon nitride cap layer 51 located thereon, to form another tungsten-containing portion 43b. In the following description, the two tungsten-containing portions 43a, 43b are collectively referred as the tungsten-containing portion 43, and the two first metal portions 41a, 41b are collectively referred as the first metal portion 41. The tungsten-containing portion 43 has a top surface 4300 (i.e., a top surface of the silicon nitride cap layer 51) that is located at a level lower than a top surface 4200 of the second metal portion 42.

The first CMP process of step 301 is similar to the first CMP process described in step 101 of the method 100, and is to remove the upper part 423 of the second metal portion 42. The first CMP process may terminate at the upper dielectric layer 362, such that in step 301, the tungsten-containing portion 43 remain intact after the first CMP process. In some embodiment, an upper region of the upper dielectric layer 362, and an upper region of the middle part 422 of the second metal portion 42 may also be removed. After the first CMP process, the middle part 422 of the second metal portion 42 is exposed.

The first polishing slurry used in step 301 may be similar to the first polishing slurry used in step 101 of the method 100, though the first inhibitor used in the step 101 may be omitted. In some embodiments, the first polishing slurry used in step 301 may include the second inhibitor used in step 302. Other operation parameters, such as the first active chemical (i.e., orthoperiodic acid (H₅IO₆)), and the pH (i.e., neutral, or alkaline, such as pH ranging from about 5.5 to about 7.5), of the first polishing slurry used in step 301 are similar to those of step 101. As such, the blanket-deposited ruthenium in the upper part 423 may be removed with a high removal rate.

By completing step 301, as shown in FIG. 10, the tungsten-containing portion 43 (especially the first metal portion 41) remains intact, and may be covered by a remaining portion of the upper dielectric 362. The second metal portion 42 has a first polished surface 4201, which is located at a level higher than the level of the top surface 4300 of the tungsten-containing portion 43.

Referring to FIG. 8 and the example illustrated in FIG. 10, the method 300 proceeds to step 302, where the base structure is subjected to a second chemical mechanical polishing (CMP) process (see the arrow P2). The second metal portion 42 is further polished, such that after the second CMP process, the first and second metal portions 41, 42 have top surfaces thereof located at substantially the same level.

In some embodiments, in step 302, as shown in FIG. 10, the middle part 422 of the second metal portion 42 is removed, along with the upper dielectric layer 362. The second CMP process of step 302 terminates at the silicon nitride cap layer 51 of the tungsten-containing portion 43. In some embodiments, an upper region of the silicon nitride cap layer 51 is etched and removed, leaving a lower region with a height ranging from about 1 nm to about 3 nm.

In the second CMP process of the method 300, a second polishing slurry similar to that of the method 100 may be employed, except that the second inhibitor is different. That is, in some embodiments, the second active chemical is hydrogen peroxide (H₂O₂), and the pH ranges from about 2.2 to about 6.5. The second active chemical, in absence of the second inhibitor, has a first etching rate to the silicon nitride cap layer 51, and a second etching rate to the second metal portion 42, and the first etching rate is greater than the second etching rate. The second inhibitor used in the second polishing slurry in the method 300 is an anionic surfactant and is configured to reduce etching of the silicon nitride cap layer 51, such that the metal portion 41 underneath the silicon nitride cap layer 51 is unaffected by the second polishing slurry (in the method 100, the second inhibitor used is to protect the first metal portion 41). Examples of the anionic surfactant include polyacrylic acid, or amino acid, or the likes, but are not limited thereto. It is noted that silicon nitride is positively charged. The negatively charged anionic surfactant physically and electrostatically adsorbs on and protect the positively charged silicon nitride cap layer 51. Inclusion of the anionic surfactant helps reduce removal rate of the silicon nitride cap layer 51, and the second polishing slurry has a higher oxide to nitride selectivity (“oxide” refers to the dielectric feature 360, while “nitride” refers to the silicon nitride cap layer 51), such that the second CMP process terminates at the silicon nitride cap layer 51, and that the first metal portion 41 is not affected by the second CMP process. In other words, in the second CMP process of the method 300, a passivation layer (including a silicon nitride film (a portion of the silicon nitride cap layer 51) with the anionic surfactant adsorbed thereon) is formed to reduce the removal rate of the silicon nitride layer 51.

Unlike the second CMP process of the method 100 (described with reference to FIGS. 3 and 4), in which the first and second metal portions 41, 42 are copolished at the same time, in the second CMP process of the method 300, the second metal portion 42 is polished, while the first metal portion 41 remain intact.

By completing step 302, for the tungsten-containing portion 43, the lower region of the silicon nitride cap layer 51, and the first metal portion 41 remain; and for the second metal portion 42, the lower part 421 remains. FIG. 11 illustrates the intermediate structure after completing step 302. The silicon nitride cap layer 51 of the tungsten-containing portion 43 is exposed, while the tungsten part (the first metal portion 41) disposed beneath and protected by the silicon nitride cap layer 51 is prevented from being exposed. Please note that the second metal portion 42 (see FIG. 9) is formed into a second conducting element 420 that includes the lower part 421, and that has a polished top surface 4202. The first metal portion 41 of the tungsten-containing portion 43 may directly serve as a first conducting element that is similar to the first conducting element 410 (see FIG. 5) obtained by the method 100.

Referring to FIG. 1 and the example illustrated in FIG. 12, the method 300 proceeds to step 303, where the silicon nitride cap layer 51 is removed from the tungsten-containing portion 43 to expose a top surface 4100 of the first metal portion 41, and a difference H2 between top surfaces 4100, 4202 of the first and second conducting elements 41, 420 ranges from about 1 nm to about 3 nm.

Removal of the silicon nitride cap layer 51 may be performed using any suitable processes and/or materials known in the art. By completing step 303, the semiconductor structure 400 (see FIG. 12) is obtained. The semiconductor structure 400 includes the first conducting element 41, or known as the first metal portion 41, and the second conducting elements 420, wherein top surfaces 4100, 4202 of the first and second conducting elements 41, 420 are substantially at the same level.

Both the method 100 and the method 300 are capable of forming semiconductor structures (e.g., the semiconductor structure 200 shown in FIG. 5 and the semiconductor structure 400 shown in FIG. 12) with conducting elements (410, 420 in FIG. 5, or 41, 420 in FIG. 12) that have top surfaces thereof located at substantially the same level. In both of the methods 100, 300, the first CMP process (step 101, step 301) is employed to rapidly remove the upper part 423 of the second metal portion 42, which is a blanket deposited ruthenium, using a strong oxidizing agent (orthoperiodic acid) as the active chemical under a neutral or alkaline condition. In addition, in both of the methods 100, 300, the second CMP process (step 102, step 302) is employed to polish the structure using a relatively weak oxidizing agent (hydrogen peroxide) as the active chemical under an acidic condition with the aid of a cationic surfactant used in the method 100 so as to avoid overpolishing of the first metal portion 41, or with the aid of an anionic surfactant used in the method 300 so as to ensure that the first metal portion 41 can be effectively protected by the silicon nitride cap layer 51. For method 100, both the first and second metal portions 41, 42 are polished at the same time to a desired level, and a cationic surfactant is used. In contrast, for method 300, the silicon nitride cap layer 51 is formed to cover the first metal portion 41 prior to the first CMP process, such that in the second CMP process, the first metal portion 41, also known as the tungsten part, is not subjected to the polishing process and remains intact, and an anionic surfactant is used. For both the methods 100 and 300, in the case that the blanket deposited upper part 423 of the second metal portion 42 is not formed, the first CMP process may be omitted.

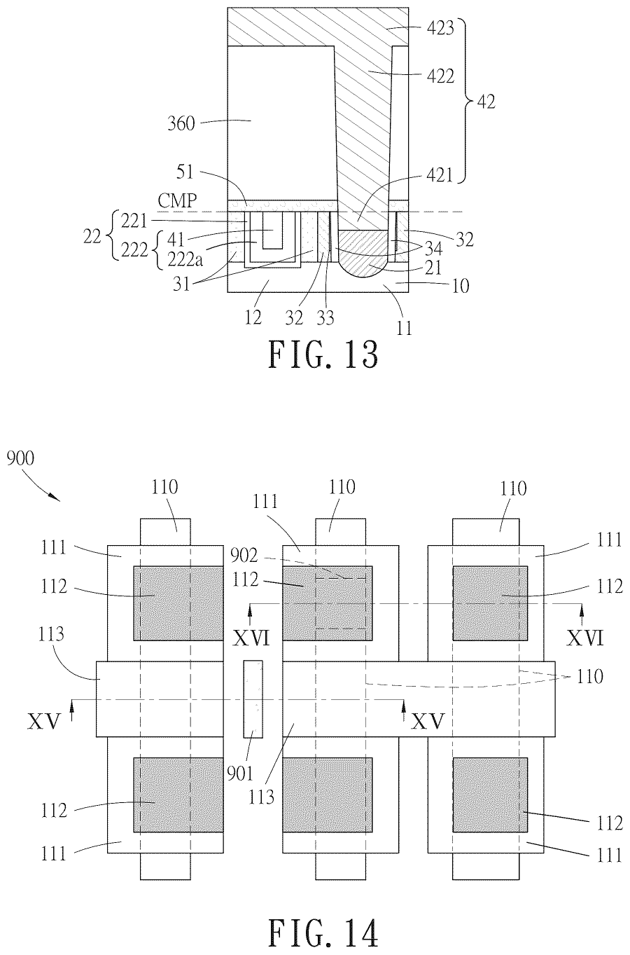

The method of the present disclosure is applicable to form conducting elements that are respectively made of ruthenium and tungsten (tungsten may be replaced by molybdenum in accordance with some embodiments), and that have top surfaces thereof located at substantially the same level. In the previous paragraphs described with reference to FIGS. 1 to 12, formation of ruthenium via and tungsten via is demonstrated. Please note that the method of the present disclosure may also be applied to form any other suitable conducting elements. FIGS. 13 and 14 show some other examples.

FIG. 13 shows a base structure that is to be formed into a semiconductor structure including a tungsten-containing metal gate and a ruthenium via. The base structure includes a source/drain portion 11, a channel 12, a source/drain contact 21, gate spacers 31, a contact etch stop layer 32, an ILD 33, and a pair of silicon nitride liners 34 that are similar to those described with reference to FIG. 2, and thus details thereof are omitted for the sake of brevity. In this exemplary example, a silicon nitride cap layer 51 is formed between a gate unit 22 and a dielectric feature 360, and the gate unit 22 includes a gate dielectric 221 that is similar to that described with reference to FIG. 2, and a gate electrode 222. The gate electrode 222 includes a tungsten part 41, and a metal section 222a that may include a conductive material such as a metal, a metal-containing nitride, a metal-containing silicide, a metal-containing carbides, or the likes, or combinations thereof. The second metal portion 42 includes the upper part 423 disposed over the dielectric feature 360, the middle part 422 disposed in the dielectric feature 360, and the lower part 421 disposed beneath a lower surface of the silicon nitride cap layer 51. The tungsten part 41 may serve as the first metal portion described with reference to FIGS. 1 to 7, or the tungsten part 41 and a portion of the silicon nitride cap layer 51 thereon may serve as the tungsten-containing portion 43 described with reference to FIGS. 8 to 12. The method 100 or 300 may be employed to form the second metal portion 42 into the ruthenium via that has a top surface at a level substantially the same as a top surface of the tungsten part 41 of the gate electrode 222. That is, the first and second CMP processes are performed to remove an upper portion of the base structure that is located above the dotted line shown in FIG. 13.

In some embodiments, when the first metal portion of the base structure is not intended to be polished and can directly serve as the first conducting element, the method 300 may be employed.

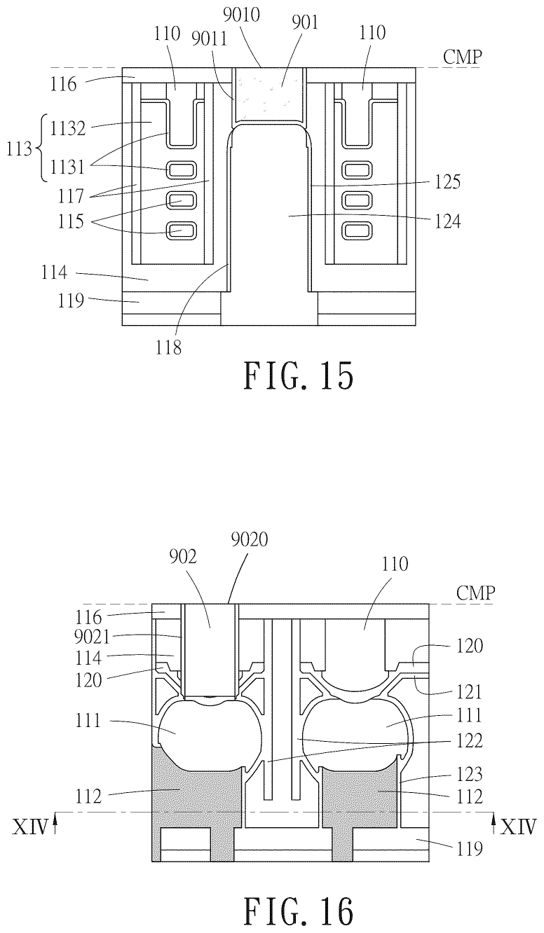

FIG. 14 is a schematic top view illustrating some elements of a semiconductor structure 900 in accordance with some embodiments. Specifically, the semiconductor structure 900 includes a tungsten front side via 901 and a ruthenium back side via 902 obtained using the method of the present disclosure in accordance with some embodiments. FIGS. 15 and 16 are cross-sectional views of the semiconductor structure 900 taken along lines XV-XV and XVI-XVI shown in FIG. 14 to illustrate the tungsten front side via 901 and the ruthenium back side via 902, respectively. Please note that FIG. 14 is merely a schematic top view, and the elements shown in FIGS. 14 to 16 are merely for illustrative purpose and may not be drawn to scale. The schematic sectional top view of the semiconductor structure 900 shown in FIG. 14 is viewed from a front side and is taken along line XIV-XIV shown in FIG. 16. Some elements shown in FIGS. 15 and 16 (e.g., a dielectric structure 114) are omitted in FIG. 14 for better illustration.

The semiconductor structure 900 exemplarily includes two gate-all around (GAA) devices, but are not limited thereto. Referring to FIGS. 14 to 16, the two GAA devices are respectively formed on two fins 110 and in the dielectric structure 114 (including an ILD, shallow trench isolations or the like). The fins 110 are formed on a substrate 116. Each of the GAA devices includes two source/drain portions 111 that are separated from each other and that are connected by channels 115. A bottom isolation 120 (or known as FBI) is formed between the fins 110 and each of the source/drain portions 111. A bottom contact etch stop layer (B-CESL) 121 is formed over the bottom isolation 120 to cover each of the source/drain portions 111. The source/drain portions 111 of different GAA devices are spaced apart from each other by cut metal gate (CMG) liners 122. Source/drain contacts 112 are respectively formed on and connected to the source/drain portions 111. The source/drain contacts 112 are surrounded by contact liners 123 (or known as MD SNR liners). The channels 115 in each of the GAA devices are surrounded by a gate unit 113, which includes a gate dielectric 1131, and a gate electrode 1132 that is separated from the channels 115 by the gate dielectric 1131. The gate unit 113 is sandwiched between two poly spacers 117. A middle contact etch stop layer (M-CESL) 119 is formed in the dielectric structure 114 and located at a front side of the gate units 113 and the source/drain contacts 112. In FIG. 14, for the GAA device drawn at upper part of the plane view, the ruthenium back side via 902 is formed to penetrate through a corresponding one of the fins 110 so as to connect with a corresponding one of the source/drain portions 111, (see also FIG. 16). In some embodiments, the ruthenium back side via 902 is surrounded by a via liner 9021. The semiconductor structure 900 also includes the tungsten front side via 901 that is located between the two gate units 113 of the two GAA devices. The tungsten front side via 901 is configured to interconnect an element (not shown) at the front side and an element at the back side of the semiconductor structure 900 (the connections are not shown in the figures). In some embodiments, the tungsten front side via 901 may serve as a feed-through via (FTV) that delivers powers from front side of the semiconductor structure 900 to back side of the semiconductor structure 900. In some embodiments, the tungsten front side via 901 is surrounded by a metal liner 9011. In certain embodiments, the tungsten front side via 901 is connected to a contact 124 which is surrounded by a contact liner 125. Materials of the substrate 116, the fins 110, the source/drain portions 111, the source/drain contacts 112 (or the contact 124), the gate dielectric 1131, the gate electrode 1132, the dielectric structure 114, and the channels 115 of the semiconductor structure 900 may be respectively similar to the materials of the substrate, the fin 10, the source/drain portions 11, the source/drain contacts 21, the gate dielectric 221, the gate electrode 222, the ILD 33, and the channels 12 of the base structure described with reference to FIG. 2, and details thereof are omitted for the sake of brevity. Each of the bottom isolation 120, the B-CESL 121, the CMG liners 122, the contact liners 123, 125, the poly spacers 117, the M-CESL 119, the via liner 9021 may be independently made of a nitride base material, such as silicon nitride, silicon oxynitride, silicon carbonitride, silicon oxycarbonitride, but are not limited thereto. The metal liner 9011 may be made of e.g., tungsten, cobalt, molybdenum, ruthenium, titanium, titanium nitride, but are not limited thereto.

After processes at the front side (e.g., forming the GAA devices, a tungsten portion for forming the tungsten front side via 901 between the GAA devices, the structures at the MEOL and the BEOL over the GAA devices and other suitable processes), the semiconductor structure 900 may be obtained by thinning-down the substrate 116 from the back side, forming a through hole (not shown) for forming the ruthenium back side via 902, depositing a ruthenium material over the substrate 116 to fill the through hole and removing an excess of the ruthenium material using the method 100 or 300 of the present disclosure. After performing the CMP processes of the method 100 or 300 from the backside (until the dotted lines shown in FIGS. 15 and 16), the tungsten portion is formed into the tungsten front side via 901, and the ruthenium material (i.e., ruthenium portion) is formed into the ruthenium back side via 902. As such, the tungsten front side via 901 and the ruthenium back side via 902 are obtained, and when viewing from the back side, a top surface 9010 of the tungsten front side via 901, and a top surface 9020 of the ruthenium back side via 902, are located at substantially the same level.

In some alternative embodiments, the semiconductor structure 900 may further include additional features, and/or some features present in the semiconductor structure 900 may be modified, replaced, or eliminated without departure from the spirit and scope of the present disclosure.

In some cases, when both the first metal portion and the second metal portion are formed with ruthenium, one single CMP process may be employed using a polishing slurry that is equivalent to the first polishing slurry adopted in step 101 (of method 100), or step 301 (of method 300) to obtain the first and second conducting elements.

The embodiments of the present disclosure have the following advantageous features. In the CMP process, hydrogen peroxide may be employed under a suitable pH condition, and with the aid of an inhibitor (e.g., the cationic surfactant in case that the silicon nitride cap layer 51 is absent, or the anionic surfactant in case that the silicon nitride cap layer 51 is present) to avoid overpolishing of the tungsten-containing portion (e.g., the silicon nitride cap layer 51, or the tungsten part in case that the silicon nitride cap layer 51 is present). As such, the tungsten part of the tungsten-containing portion and the ruthenium portion are respectively formed into conducting elements that have top surfaces thereof located at substantially the same level. The semiconductor structure having a reduced cell height and including the ruthenium conducting elements may have reduced contact resistance and thus enhanced performance, such as speed improvement.

In accordance with some embodiments of the present disclosure, a method for forming a semiconductor structure includes: performing a chemical mechanical polishing (CMP) process on a base structure including therein a first metal portion and a second metal portion using an acidic polishing slurry, the acidic polishing slurry including an active chemical and an inhibitor which protects the first metal portion from being overpolished, a metal material of the first metal portion being different from a metal material of the second metal portion.

In accordance with some embodiments of the present disclosure, the metal material of the first metal portion includes one of tungsten and molybdenum, and the metal material of the second metal portion includes ruthenium, the active chemical, in absence of the inhibitor, having a first etching rate with respect to the first metal portion, and a second etching rate with respect to the second metal portion, the first etching rate being greater than the second etching rate.

In accordance with some embodiments of the present disclosure, the inhibitor is a cationic surfactant.

In accordance with some embodiments of the present disclosure, the base structure includes a silicon nitride cap layer covering the first metal portion, the active chemical, in absence of the inhibitor, having a first etching rate with respect to the silicon nitride cap layer, and a second etching rate with respect to the second metal portion, the first etching rate being greater than the second etching rate.

In accordance with some embodiments of the present disclosure, the inhibitor is an anionic surfactant.

In accordance with some embodiments of the present disclosure, the method further includes removing the silicon nitride cap layer after performing the CMP process.

In accordance with some embodiments of the present disclosure, the metal material of the first metal portion is one of tungsten and molybdenum, and the metal material of the second metal portion is ruthenium, and the active chemical is hydrogen peroxide.

In accordance with some embodiments of the present disclosure, a method for forming a semiconductor structure includes: forming a base structure including therein a tungsten-containing portion and a ruthenium portion, a top surface of the ruthenium portion being located at a level higher than a level of a top surface of the tungsten-containing portion; performing a first chemical mechanical polishing (CMP) process on the base structure by using a first polishing slurry to remove an upper part of the ruthenium portion, such that the ruthenium portion, after the first CMP process, has a first polished surface located at a level that is higher than the level of the top surface of the tungsten-containing portion; and after the first CMP process, performing a second CMP process on the base structure by using a second polishing slurry to remove a middle part of the ruthenium portion and to expose the tungsten-containing portion, the second polishing slurry being different from the first polishing slurry and including an active chemical and an inhibitor which protects the tungsten-containing portion from being overpolished in the second CMP process.

In accordance with some embodiments of the present disclosure, in the second CMP process, a passivation layer is formed on the tungsten-containing portion.

In accordance with some embodiments of the present disclosure, the passivation layer is a tungsten trioxide layer with a cationic surfactant adsorbed thereon, or a silicon nitride film with an anionic surfactant adsorbed thereon.

In accordance with some embodiments of the present disclosure, the first polishing slurry includes an inhibitor same as the inhibitor of the second polishing slurry.

In accordance with some embodiments of the present disclosure, the tungsten-containing portion includes a tungsten part, and a silicon nitride cap layer disposed on and in direct contact with the tungsten part, a top surface of the silicon nitride cap layer serving as the top surface of the tungsten-containing portion prior to the second CMP process, before the second CMP process, the silicon nitride cap layer has a thickness ranging from 3 nm to 5 nm, and after the second CMP process, the silicon nitride cap layer is exposed and has a thickness ranging from 1 nm to 3 nm, while the tungsten part disposed beneath the silicon nitride cap layer is prevented from being exposed.

In accordance with some embodiments of the present disclosure, the inhibitor is an anionic surfactant.

In accordance with some embodiments of the present disclosure, an active chemical of the first polishing slurry includes orthoperiodic acid and the active chemical of the second polishing slurry includes hydrogen peroxide.

In accordance with some embodiments of the present disclosure, the first CMP process is performed at a pH not smaller than 5.5, and the second CMP process is performed at a pH not greater than 6.5.

In accordance with some embodiments of the present disclosure, a method for forming a semiconductor structure includes: forming a tungsten-containing portion in a dielectric feature; forming a ruthenium portion which includes an upper section on the dielectric feature, and a lower section in the dielectric feature; performing a first chemical mechanical polishing (CMP) process by using a first polishing slurry to remove the upper section of the ruthenium portion and to expose the dielectric feature; and after the first CMP process, performing a second CMP process by using a second polishing slurry to remove an upper region of the lower section and an upper dielectric layer of the dielectric feature so as to expose the tungsten-containing portion, the second polishing slurry being different from the first polishing slurry and including an active chemical and an inhibitor which protects the tungsten-containing portion from being overpolished in the second CMP process.

In accordance with some embodiments of the present disclosure, an active chemical of the first polishing slurry includes orthoperiodic acid, and the active chemical of the second polishing slurry includes hydrogen peroxide.

In accordance with some embodiments of the present disclosure, the inhibitor includes a cationic surfactant.

In accordance with some embodiments of the present disclosure, the tungsten-containing portion includes a tungsten part and a silicon nitride cap layer disposed between the dielectric feature and the tungsten part; after the second CMP process, the silicon nitride cap layer is exposed while the tungsten part protected by the silicon nitride cap layer is prevented from being exposed; and the active chemical, in absence of the inhibitor, has a first etching rate with respect to the silicon nitride cap layer, and a second etching rate with respect to the second metal portion, the first etching rate being greater than the second etching rate.

In accordance with some embodiments of the present disclosure, the inhibitor includes an anionic surfactant.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
performing a chemical mechanical polishing (CMP) process on a base structure including therein a first metal portion and a second metal portion using an acidic polishing slurry, the acidic polishing slurry including an active chemical and an inhibitor which protects the first metal portion from being overpolished, a metal material of the first metal portion being different from a metal material of the second metal portion.

2. The method according to claim 1, wherein the metal material of the first metal portion includes one of tungsten and molybdenum, and the metal material of the second metal portion includes ruthenium,
the active chemical, in absence of the inhibitor, having a first etching rate with respect to the first metal portion, and a second etching rate with respect to the second metal portion, the first etching rate being greater than the second etching rate.

3. The method according to claim 2, wherein the inhibitor is a cationic surfactant.

4. The method according to claim 1, wherein the base structure includes a silicon nitride cap layer covering the first metal portion,
the active chemical, in absence of the inhibitor, having a first etching rate with respect to the silicon nitride cap layer, and a second etching rate with respect to the second metal portion, the first etching rate being greater than the second etching rate.

5. The method according to claim 4, wherein the inhibitor is an anionic surfactant.

6. The method according to claim 4, further comprising:
removing the silicon nitride cap layer after performing the CMP process.

7. The method according to claim 1, wherein
the metal material of the first metal portion is one of tungsten and molybdenum, and the metal material of the second metal portion is ruthenium, and
the active chemical is hydrogen peroxide.

8. A method for forming a semiconductor structure, comprising:
forming a base structure including therein a tungsten-containing portion and a ruthenium portion, a top surface of the ruthenium portion being located at a level higher than a level of a top surface of the tungsten-containing portion;
performing a first chemical mechanical polishing (CMP) process on the base structure by using a first polishing slurry to remove an upper part of the ruthenium portion, such that the ruthenium portion, after the first CMP process, has a first polished surface located at a level that is higher than the level of the top surface of the tungsten-containing portion; and
after the first CMP process, performing a second CMP process on the base structure by using a second polishing slurry to remove a middle part of the ruthenium portion and to expose the tungsten-containing portion, the second polishing slurry being different from the first polishing slurry and including an active chemical and an inhibitor which protects the tungsten-containing portion from being overpolished in the second CMP process.

9. The method according to claim 8, wherein in the second CMP process, a passivation layer is formed on the tungsten-containing portion.

10. The method according to claim 8, wherein the passivation layer is a tungsten trioxide layer with a cationic surfactant adsorbed thereon, or a silicon nitride film with an anionic surfactant adsorbed thereon.

11. The method according to claim 8, wherein the first polishing slurry includes an inhibitor same as the inhibitor of the second polishing slurry.

12. The method according to claim 8, wherein:
the tungsten-containing portion includes a tungsten part, and a silicon nitride cap layer disposed on and in direct contact with the tungsten part, a top surface of the silicon nitride cap layer serving as the top surface of the tungsten-containing portion prior to the second CMP process,
before the second CMP process, the silicon nitride cap layer has a thickness ranging from 3 nm to 5 nm, and
after the second CMP process, the silicon nitride cap layer is exposed and has a thickness ranging from 1 nm to 3 nm, while the tungsten part disposed beneath the silicon nitride cap layer is prevented from being exposed.

13. The method according to claim 12, wherein the inhibitor is an anionic surfactant.

14. The method according to claim 8, wherein an active chemical of the first polishing slurry includes orthoperiodic acid and the active chemical of the second polishing slurry includes hydrogen peroxide.

15. The method according to claim 14, wherein the first CMP process is performed at a pH not smaller than 5.5, and the second CMP process is performed at a pH not greater than 6.5.

16. A method for forming a semiconductor structure, comprising:
forming a tungsten-containing portion in a dielectric feature;
forming a ruthenium portion which includes an upper section on the dielectric feature, and a lower section in the dielectric feature;
performing a first chemical mechanical polishing (CMP) process by using a first polishing slurry to remove the upper section of the ruthenium portion and to expose the dielectric feature; and
after the first CMP process, performing a second CMP process by using a second polishing slurry to remove an upper region of the lower section and an upper dielectric layer of the dielectric feature so as to expose the tungsten-containing portion, the second polishing slurry being different from the first polishing slurry and including an active chemical and an inhibitor which protects the tungsten-containing portion from being overpolished in the second CMP process.

17. The method according to claim 16, wherein an active chemical of the first polishing slurry includes orthoperiodic acid, and the active chemical of the second polishing slurry includes hydrogen peroxide.

18. The method according to claim 17, wherein the inhibitor includes a cationic surfactant.

19. The method according to claim 16, wherein:
the tungsten-containing portion includes a tungsten part and a silicon nitride cap layer disposed between the dielectric feature and the tungsten part;
after the second CMP process, the silicon nitride cap layer is exposed while the tungsten part protected by the silicon nitride cap layer is prevented from being exposed; and
the active chemical, in absence of the inhibitor, has a first etching rate with respect to the silicon nitride cap layer, and a second etching rate with respect to the second metal portion, the first etching rate being greater than the second etching rate.

20. The method according to claim 19, wherein the inhibitor includes an anionic surfactant.
